(19) United States
(12) Patent Application Publication
(10) Pub. No.: US 2021/0280530 A1
(43) Pub. Date: Sep. 9, 2021

(54) ELECTRONIC PACKAGE

(71) Applicant: SILICONWARE PRECISION INDUSTRIES CO., LTD., Taichung (TW)

(72) Inventors: Chi-Jen Chen, Taichung (TW); Chih-Hsun Hsu, Taichung (TW); Chee-Key Chung, Taichung (TW); Jia-Wei Pan, Taichung (TW); Chang-Fu Lin, Taichung (TW)

(73) Assignee: SILICONWARE PRECISION INDUSTRIES CO., LTD., Taichung (TW)

(21) Appl. No.: 16/876,460

(22) Filed: May 18, 2020

(30) Foreign Application Priority Data
Mar. 6, 2020 (TW) 109107444

(51) Int. Cl. H01L 23/00; H01L 23/367; H01L 23/31; H01L 23/498

(52) U.S. Cl. CPC H01L 23/562; H01L 23/3675; H01L 23/3135; H01L 2924/3512; H01L 24/16; H01L 2224/16227; H01L 23/49838

(57) ABSTRACT

Provided is an electronic package, including a multi-chip packaging body with a plurality of electronic elements and a stress buffer layer disposed on the multi-chip packaging body. The stress buffer layer is in contact with the plurality of electronic elements so as to cause stresses to be evenly distributed in the stress buffer layer instead of being concentrated in specific areas, thereby preventing structural stresses from being concentrated in corners of the electronic elements.

### CROSS-REFERENCE TO RELATED APPLICATIONS

This application claims priority to Taiwan Application Serial No. 109107444, filed on Mar. 6, 2020. The entirety of the above-mentioned patent application is hereby incorporated by reference herein and made a part of this specification.

### BACKGROUND

### 1. Technical Field

The present disclosure relates to packaging structures, and more particularly, to a heat dissipation type electronic package.

### 2. Description of Related Art

Along with the progress of technology, the demand for electronic products with heterogeneous integration has increased. Therefore, multi-chip packaging structures (MCM/MCP) have been developed.

As shown in multi-chip packaging structure 1 of FIG. 1, a plurality of semiconductor chips 11 are bonded to a packaging substrate 10 through a plurality of solder bumps 13, and an underfill 14 is encapsulated the solder bumps 13 and the plurality of semiconductor chips 11. By packaging the plurality of semiconductor chips 11 into a module, more I/O counts can be provided, the computing power of processors can be greatly increased and signal transmission delay can be reduced. Therefore, such a packaging structure is applicable to high-end products with high-density circuits, a high transmission speed, a large number of stack layers or a large size design.

However, for the multi-chip packaging structure 1 of FIG. 1 (an encapsulant and a heat dissipation element are omitted in the drawing), as more and more functions are required, the number of the semiconductor chips 11 is increasing and hence the overall planar packaging area of the packaging substrate 10 becomes larger and larger. Therefore, at high temperature, the overall structure warps upward along a dashed line L1, whereas at room temperature, the overall structure warps downward along a dashed line L2, thus resulting in multiple times of expansion of the multi-chip packaging structure 1 in an arrow direction X1 or contraction of the multi-chip packaging structure 1 in an arrow direction X2. As such, because of discontinuity of stresses between each of the semiconductor chips 11, the stresses in corners of the semiconductor chips 11 become too large. Consequently, cracking easily occurs to the underfill 14 between each of the semiconductor chips 11, thus adversely affecting the product reliability and reducing the product yield.

Therefore, how to overcome the above-described drawbacks of the prior art has become an urgent issue in the art.

### SUMMARY

In view of the above-described drawbacks, the present disclosure provides an electronic package, which comprises: a multi-chip packaging body having a plurality of electronic elements and a covering layer bonded to the plurality of electronic elements; and a stress buffer layer disposed on the multi-chip packaging body so as to come into contact with the plurality of electronic elements and the covering layer.

In an embodiment, at least two of the plurality of electronic elements are arranged separately from one another.

In an embodiment, the covering layer is formed between any two of the plurality of electronic elements.

In an embodiment, the covering layer is an underfill.

In an embodiment, the multi-chip packaging body further comprises a carrier structure carrying and electrically connected to the plurality of electronic elements, and the covering layer is formed on the carrier structure. For example, the carrier structure is a coreless circuit structure.

In an embodiment, the multi-chip packaging body further comprises an encapsulant encapsulating the plurality of electronic elements and the covering layer. For example, the stress buffer layer is in contact with the encapsulant. Alternatively, the electronic elements have a surface flush with an upper surface of the encapsulant.

In an embodiment, the electronic package further comprises a heat dissipation element bonded onto the plurality of electronic elements. For example, the heat dissipation element is bonded onto the stress buffer layer through a heat dissipation material. Alternatively, the stress buffer layer is disposed between the plurality of electronic elements and the heat dissipation element.

In an embodiment, the stress buffer layer is a metal layer.

According to the electronic package of the present disclosure, the stress buffer layer is disposed on the multi-chip packaging body and connects the inactive surface of each of the electronic elements and the surface of the covering layer so as to cause stresses to be evenly distributed in the stress buffer layer instead of being concentrated in specific areas. Compared with the prior art, the present disclosure effectively prevents structural stresses from being concentrated in corners of the electronic elements and hence avoids cracking of the electronic elements or the covering layer, thereby improving the product reliability and increasing the product yield.

### BRIEF DESCRIPTION OF THE DRAWINGS

FIG. 1 is a schematic cross-sectional view of a conventional multi-chip packaging structure;

FIG. 2 is a schematic cross-sectional view of an electronic package according to the present disclosure; and

FIG. 2′ is a partially enlarged schematic view of FIG. 2.

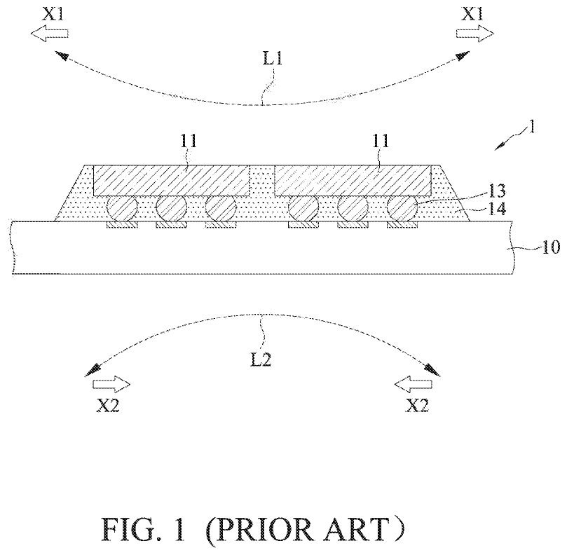

### DETAILED DESCRIPTION

The following illustrative embodiments are provided to illustrate the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first,” “second,” “on,” “a,” etc., are merely for illustrative purposes and should not be construed to limit the scope of the present disclosure.

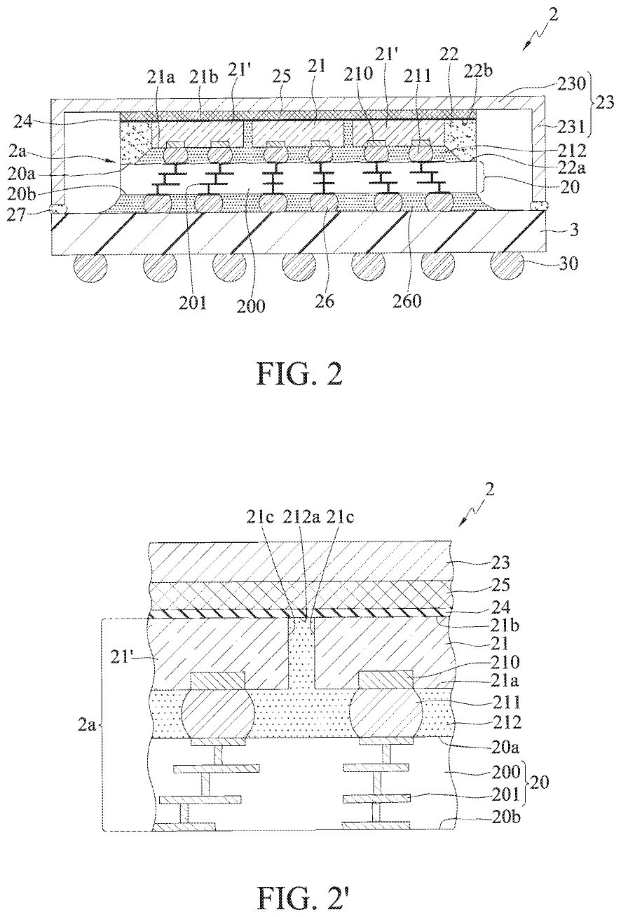

FIGS. 2 and 2′ are schematic cross-sectional views of an electronic package 2 according to the present disclosure. As shown in FIGS. 2 and 2′, the electronic package 2 includes a multi-chip packaging body 2a (which includes a carrier structure 20, a plurality of electronic elements 21, 21′ and an encapsulant 22), a stress buffer layer 24, a heat dissipation material 25, and a heat dissipation element 23.

The carrier structure 20 is in the form of a carrier board, which is, for example, a packaging substrate having a core layer, a coreless circuit structure, a through silicon interposer (TSI) having through silicon vias (TSVs), and so on.

In an embodiment, the carrier structure 20 is a coreless circuit structure, which comprises at least one insulating layer 200 and at least one circuit layer 201 such as a fan-out redistribution layer (RDL) bonded to the insulating layer 200. Also, the carrier structure 20 can be a lead frame, a wafer, or other board having metal routing. But it should be noted that the carrier structure 20 is not limited to the above-described examples.

Moreover, the carrier structure 20 has a first side 20a and a second side 20b opposite to the first side 20a, and a plurality of conductors 26 are formed at the second side 20b of the carrier structure 20, so that the electronic package 2 can be mounted to a packaging substrate 3 through the conductors 26, and an underfill 260 can be encapsulated the conductors 26. Alternatively, the electronic package 2 can be mounted to an electronic device such as a circuit board (not shown) through the conductors 26. For example, the conductors 26 are metal posts such as copper posts, metal bumps encapsulating insulating blocks, solder balls, solder balls having copper core, or the like.

Further, the carrier board of the carrier structure 20 can be fabricated through various fabrication processes. For example, the circuit layer 201 is fabricated through a wafer fabrication process, and silicon nitride or silicon oxide is formed by chemical vapor deposition (CVD) as the insulating layer 200. Alternatively, the circuit layer 201 can be formed through a common non-wafer fabrication process, and a low-cost polymer dielectric material such as polyimide (PI), polybenzoxazole (PBO), prepreg (PP), a molding compound, a photosensitive dielectric layer or the like is formed by coating as the insulating layer 200.

The plurality of electronic elements 21, 21′ are arranged separately from one another on the first side 20a of the carrier structure 20. Each of the electronic elements 21, 21′ can be an active element such as a semiconductor chip, a passive element such as a resistor, a capacitor or an inductor, or a combination thereof.

In an embodiment, the electronic element 21, 21′ is a semiconductor chip, which has an active surface 21a with electrode pads 210 and an inactive surface 21b opposite to the active surface 21a. The electrode pads 210 of the active surface 21a are disposed on and electrically connected to the circuit layer 201 of the first side 20a of the carrier structure 20 in a flip-chip manner through a plurality of conductive bumps 211. The conductive bumps 211 are made of such as a solder material, metal pillars or the like. Further, a covering layer 212 such as an underfill is formed to encapsulate the conductive bumps 211. In another embodiment, the electronic element 21, 21′ can be electrically connected to the circuit layer 201 of the carrier structure 20 through a plurality of bonding wires (not shown) in a wire-bonding manner. In a further embodiment, the electronic element 21, 21′ can be in direct contact with the circuit layer 201 of the carrier structure 20. Therefore, electronic elements with required types and quantities can be disposed on the carrier structure 20 so as to improve the electrical performance thereof. The manner in which the electronic elements 21, 21′ electrically connect the carrier structure 20 can be varied without being limited to above-described examples.

Further, the covering layer 212 is formed between each of the electronic elements 21, 21′, for example, extending and disposing along side surfaces 21c of the electronic elements 21, 21′, and the inactive surface 21b of each of the electronic elements 21, 21′ is flush with an upper surface 212a of the covering layer 212.

The encapsulant 22 is formed on the first side 20a of the carrier structure 20 to encapsulate the electronic elements 21, 21′ and the covering layer 212.

In an embodiment, the encapsulant 22 has a first surface 22a and a second surface 22b opposite to the first surface 22a. The first surface 22a is bonded to the first side 20a of the carrier structure 20. The inactive surfaces 21b of the electronic elements 21 are flush with the second surface 22b of the encapsulant 22 so as to expose the electronic elements 21 from the second surface 22b of the encapsulant 22.

Further, the encapsulant 22 is made of an insulating material, such as polyimide or epoxy, and formed by molding, lamination or coating.

The stress buffer layer 24 is disposed on the multi-chip packaging body 2a to come into contact with the plurality of electronic elements 21, 21′ and the covering layer 212.

In an embodiment, the stress buffer layer 24 is a metal layer, such as a copper layer, and is formed on the inactive surface 21b of each of the electronic elements 21, 21′, the upper surface 212a of the covering layer 212 and the second surface 22b of the encapsulant 22 by sputtering or other means so as to come into contact with the plurality of electronic elements 21, 21′, the covering layer 212 and the encapsulant 22.

Further, by forming the stress buffer layer 24 through sputtering, the fabrication cost can be reduced and the fabrication process can be simplified so as to facilitate mass production.

The heat dissipation material 25 is disposed on the stress buffer layer 24. The heat dissipation material 25 is a thermal interface material (TIM), such as a high thermally conductive metal adhesive material.

The heat dissipation element 23 is bonded onto the stress buffer layer 24 through the heat dissipation material 25. As such, the heat dissipation element 23, the heat dissipation material 25 and the stress buffer layer 24 serve as a heat dissipation mechanism for the electronic elements 21, 21′.

In an embodiment, the heat dissipation element 23 has a heat dissipation body 230 and a plurality of support legs 231 disposed on a lower side of the heat dissipation body 230. The heat dissipation body 230 is in the form of a heat sink and the lower side thereof is in contact with the heat dissipation material 25. The support legs 231 are bonded onto the packaging substrate 3 or the first side 20a of the carrier structure 20 through an adhesive layer 27. It should be noted that aspects of the heat dissipation element 23 are not limited to the above-described examples. For example, the heat dissipation element 23 can be in the form of a sheet body without the support legs 231.

Further, the stress buffer layer 24 is disposed between the plurality of electronic elements 21, 21′ and the heat dissipation element 23.

Furthermore, in subsequent processes, a plurality of conductive elements 30 can be mounted to a lower side of the packaging substrate 3 for connecting with an electronic device such as a circuit board (not shown). For example, the conductive elements 30 are metal posts such as copper posts, metal bumps encapsulating insulating blocks, solder balls, solder balls having copper core, or the like.

According to the electronic package 2 of the present disclosure, the stress buffer layer 24 is disposed on the multi-chip packaging body 2a and connects the inactive surface 21b of each of the electronic elements 21, 21′ and the upper surface 212a of the covering layer 212 so as to cause stresses to be evenly distributed in the stress buffer layer 24 instead of being concentrated in specific areas. Compared with the prior art, when the overall planar packaging area of the carrier structure 20 of the electronic package 2 becomes larger, the present disclosure effectively prevents structural stresses from being concentrated in corners of the electronic elements 21, 21′ and hence avoids cracking of the electronic elements 21, 21′ or the covering layer 212, thereby improving the product reliability and increasing the product yield.

The above-described descriptions of the detailed embodiments are only to illustrate the preferred implementation according to the present disclosure, and it is not to limit the scope of the present disclosure. Accordingly, all modifications and variations completed by those with ordinary skill in the art should fall within the scope of present disclosure defined by the appended claims.

What is claimed is:

1. An electronic package, comprising:
a multi-chip packaging body having a plurality of electronic elements and a covering layer bonded to the plurality of electronic elements; and
a stress buffer layer disposed on the multi-chip packaging body, the stress buffer layer being into contact with the plurality of electronic elements and the covering layer.

2. The electronic package of claim 1, wherein at least two of the plurality of electronic elements are arranged separately from one another.

3. The electronic package of claim 1, wherein the covering layer is formed between any two of the plurality of electronic elements.

4. The electronic package of claim 1, wherein the covering layer is an underfill.

5. The electronic package of claim 1, wherein the multi-chip packaging body further comprises a carrier structure carrying and electrically connected to the plurality of electronic elements, and the covering layer is formed on the carrier structure.

6. The electronic package of claim 5, wherein the carrier structure is a coreless circuit structure.

7. The electronic package of claim 1, wherein the multi-chip packaging body further comprises an encapsulant encapsulating the plurality of electronic elements and the covering layer.

8. The electronic package of claim 7, wherein the stress buffer layer is in contact with the encapsulant.

9. The electronic package of claim 7, wherein the electronic elements have a surface flush with an upper surface of the encapsulant.

10. The electronic package of claim 1, further comprising a heat dissipation element bonded onto the plurality of electronic elements.

11. The electronic package of claim 10, wherein the heat dissipation element is bonded onto the stress buffer layer through a heat dissipation material.

12. The electronic package of claim 10, wherein the stress buffer layer is disposed between the plurality of electronic elements and the heat dissipation element.

13. The electronic package of claim 1, wherein the stress buffer layer is a metal layer.
